(19) United States
(12) Patent Application Publication
(10) Pub. No.: US 2026/0095161 A1
(43) Pub. Date: Apr. 2, 2026

(54) Low Area Flip-Flop

(71) Applicant: TEXAS INSTRUMENTS INCORPORATED, Dallas, TX (US)

(72) Inventors: Arnab Khawas, Bangalore (IN); Gokul Sabada, Bangalore (IN); Badarish Subbannavar, Bangalore (IN); Suvam Nandi, Bangalore (IN)

(21) Appl. No.: 18/901,811

(22) Filed: Sep. 30, 2024

(51) Int. Cl. H03K 3/037

(52) U.S. Cl. CPC H03K 3/0372

(57) ABSTRACT

A circuit includes multiple latches that share pull-down or pull-up functionality. The sharing between the latches may allow for some transistors to be omitted. Thus, some logic circuits that include multiple latches may reduce a quantity of NMOS transistors and/or a quantity of PMOS transistors by sharing pull-down or pull-up functionality among the latches.

### TECHNICAL FIELD

The present disclosure relates generally to an electronic system and, in particular embodiments, to a low-area flip-flop.

### BACKGROUND

Flip-flops may be used in a variety of different applications, such as clock dividers, memory elements, and the like.

### SUMMARY

In accordance to an embodiment, a circuit includes: a first latch having a first logic gate that includes a first transistor having first and second current path terminals; and a second latch having a second logic gate that includes a second transistor having first and second current path terminals, where the first current path terminal of the first transistor is shorted to the second current path terminal of the second transistor, and where the second current path terminal of the first transistor is coupled to a ground terminal.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is an illustration of an example flip-flop, according to some embodiments;

FIG. 2 is an example transistor-level illustration of the flip-flop of FIG. 1, according to some embodiments;

FIG. 3 is an illustration of an example flip-flop, according to some embodiments;

FIG. 4 is an illustration of an example flip-flop, according to some embodiments;

FIG. 5 is an example transistor-level illustration of the flip-flop of FIG. 4, according to some embodiments;

FIG. 6 is an illustration of an example scan flip-flop, according to some embodiments;

FIG. 7 illustrates an example multi-bit flip-flop, according to some embodiments;

FIG. 8 is an illustration of an example multi-bit flip-flop, according to some embodiments;

FIGS. 9-12 illustrate operation of the multi-bit flip-flop of FIG. 8, according to some embodiments;

FIG. 13 is an illustration of an example multi-but flip-flop, according to some embodiments; and

FIG. 14 is an illustration of an example multi-bit flip-flop, according to some embodiments.

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Various embodiments provide architectures that may reduce a quantity of transistors in a latch-based device, such as a flip-flop. In one embodiment, a scan flip-flop having asynchronous clear functionality may include a reduced quantity of transistors. Similarly, a scan flip-flop having asynchronous preset functionality may also include a reduced quantity of transistors. The concepts may be extended to multi-bit flip-flops, whether having asynchronous clear functionality or preset functionality.

Savings of a few transistors (or even a single transistor) in a flip-flop (such as a flip-flop implemented as a standard cell) may advantageously result in noticeable savings of semiconductor area, e.g., when a given flip-flop design is used a relatively large number of times in an integrated circuit.

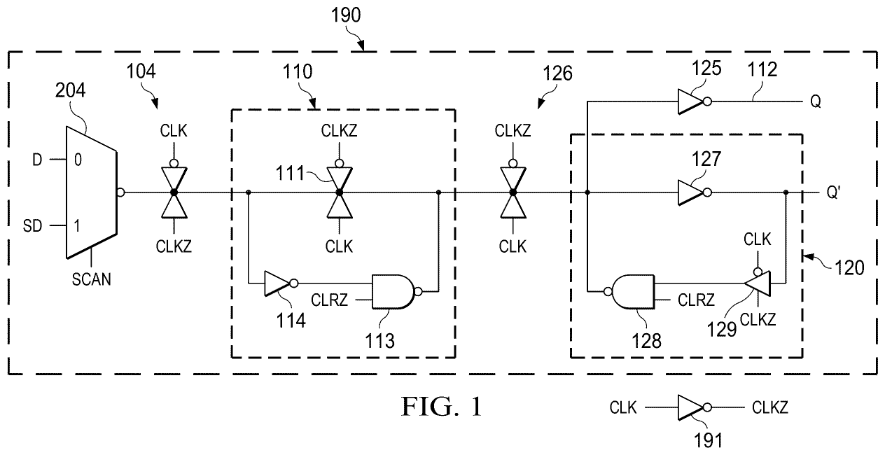

FIG. 1 is an illustration of flip-flop 190, according to some embodiments. Flip-flop 190 includes inverting multiplexer 204, having an input for functional data (d) and scan data (sd). When the scan signal is a digital 0, the inverting multiplexer 204 selects the functional data input, and when the scan signal is a digital 1, the inverting multiplexer 204 selects the scan data input. The output of the inverting multiplexer 204 is coupled to an input of transmission gate 104. At transmission gate 104, when the clock signal (clk) is a digital 0, then the transmission gate 104 is in an ON state and passes the output of the inverting multiplexer 204 to the master latch 110. When clk is a digital 1, the transmission gate 104 is in an OFF state and isolates the output of inverting multiplexer 204 from the input of master latch 110. Inverter 191 receives clk and outputs clkz.

Transmission gate 126 is coupled between an output of master latch 110 and an input of slave latch 120. The transmission gate 126 achieves an ON state when the clock signal clk is a digital 1 and achieves and OFF state when the clock signal clk is a digital 0. The master latch 110 may store a bit, such as a digital 1 or a digital 0, and the slave latch 120 may receive and store that value from the master latch 110 in response to a clock edge that turns transmission gate 126 ON. Otherwise, the input of the slave latch 120 is isolated from the output of master latch 110.

Master latch 110 includes an inverter 114 coupled to the input of master latch 110 and a transmission gate 111 coupled to the input of master latch 110. The output of inverter 114 is received by an input of NAND gate 113. The output of NAND gate 113 is coupled to the output of master latch 110 and to the output of transmission gate 111.

Slave latch 120 includes an inverter 127 having its input coupled to the output of transmission gate 126. The output of inverter 127 is coupled to an input of tri-state buffer 129. In some examples, a tri-state buffer may be implemented by a tri-state inverter having its output coupled to the input of an inverter, though the scope of embodiments may include any appropriate architecture for tri-state buffer 129. Tri-state buffer 129 is controlled by the clock signal clkz. An output of tri-state buffer 129 is coupled to an input of NAND gate 128. The output of NAND gate 128 is coupled to the input of inverter 127 as well as to the input of inverter 125. In this example, latch 120 includes cross-coupled inversion by virtue of NAND gate 128 and inverter 127. The output node 112 allows another device (not shown) to receive the output value (q). In some embodiments, node 112 may be used as a data output of flip-flop 190, e.g., to avoid directly loading slave latch 120. For example, in some embodiments, node 112 is the output of the flip-flop 190 and may be connected to other circuits (not shown in FIG. 1).

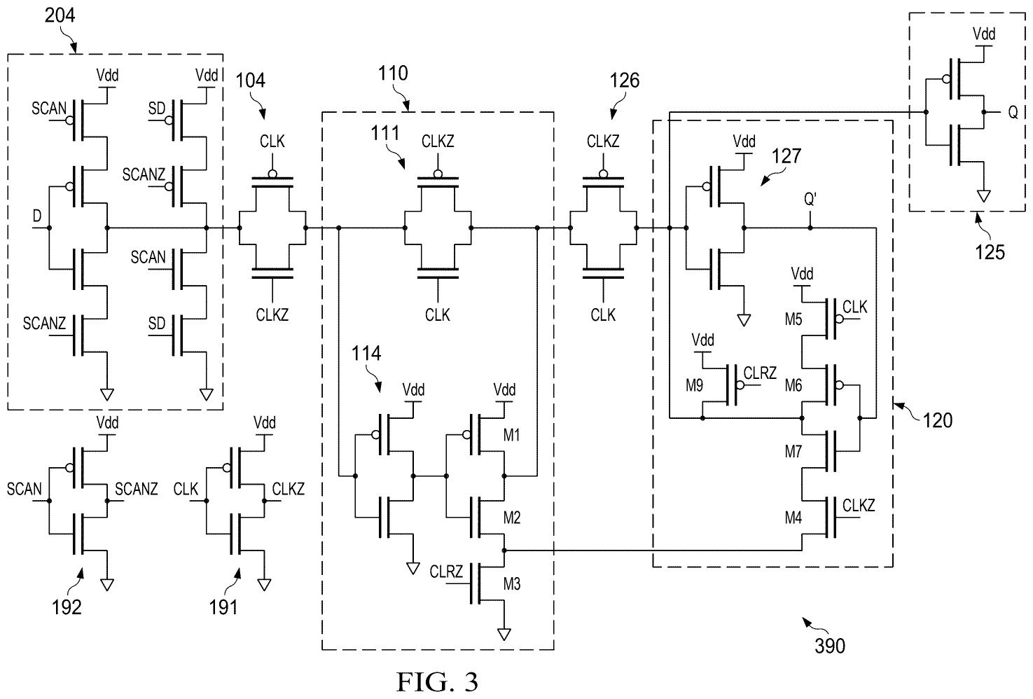

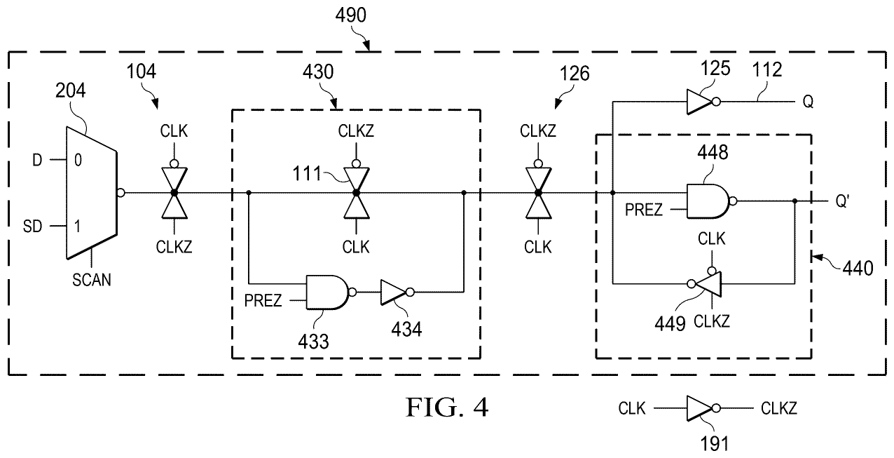

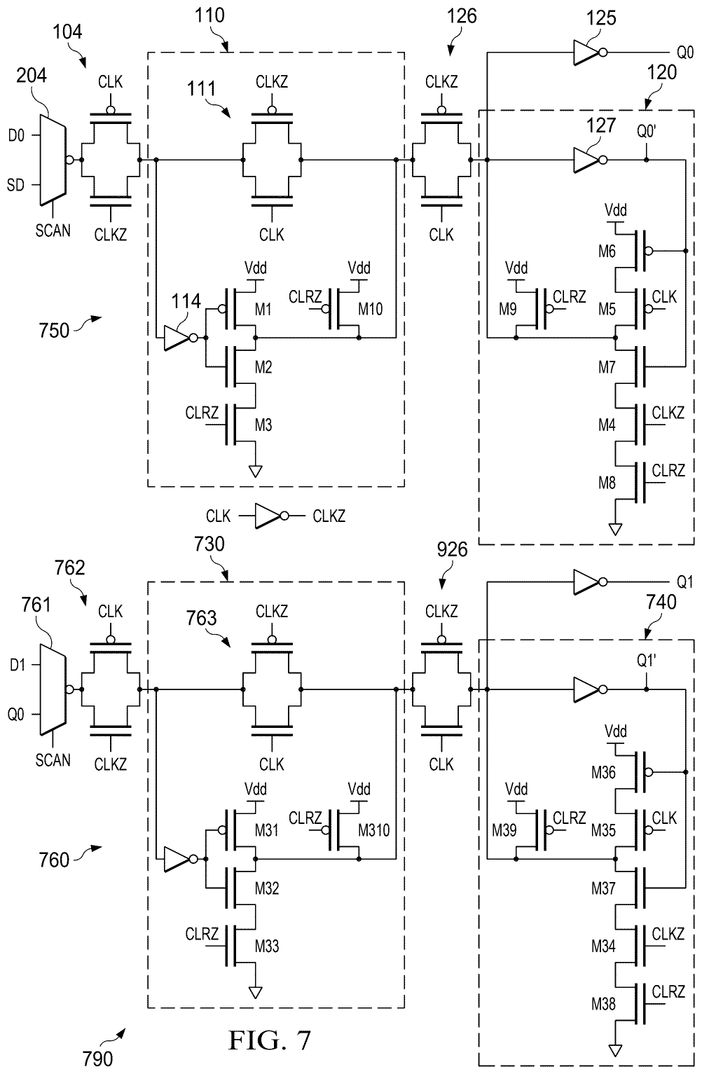

The signals q and q′ may be similar or identical, though there may be some amount of (e.g., negligible) timing delay or gain difference between the two. In some embodiments, inverter 125 may be omitted and inverter 127 may be used for both driving the input of inverter 129 and as the output of flip-flop 190. The same similar or identical relationship holds for q and q′ in FIGS. 3 and 4, for q0 and q0′ in FIGS. 7, 8, 13 and 14, and for q1 and q1′ in FIGS. 7, 8, 13 and 14.

NAND gate 113 provides asynchronous clear functionality for the master latch 110, and NAND gate 128 provides asynchronous clear functionality for the slave latch 120. In this example, the asynchronous clear signal (clrz) is an active-low signal. When the asynchronous clear signal is a digital 1, then the flip-flop 190 passes the functional data (d) or the scan data (sd) with each clock edge. When the asynchronous clear signal is a digital 0, then both the master latch 110 and the slave latch 120 assume a state of digital 0. The logic of the flip-flop 190 is such that there is asynchronous clear control over both the master latch 110 and the slave latch 120 to reset flip-flop 190 irrespective of the state of the clock signal when the clear signal clrz is a digital 0. When the clear signal is a digital 0, the output may be driven by the slave latch 120 (when clk is a digital 0) and may be driven by the master latch 110 (when clk is a digital 1).

In some embodiments, an integrated circuit (IC) includes a plurality of flip-flops 390, the IC generating signals clk and clkz (e.g., using inverter 190), and providing such generated signals to all of the plurality of flip-flops 190. Thus, in some embodiments, inverter 191 is external to flip-flop 190, and only one inverter 191 may be used for providing signals clkz to the plurality of flip-flops 190.

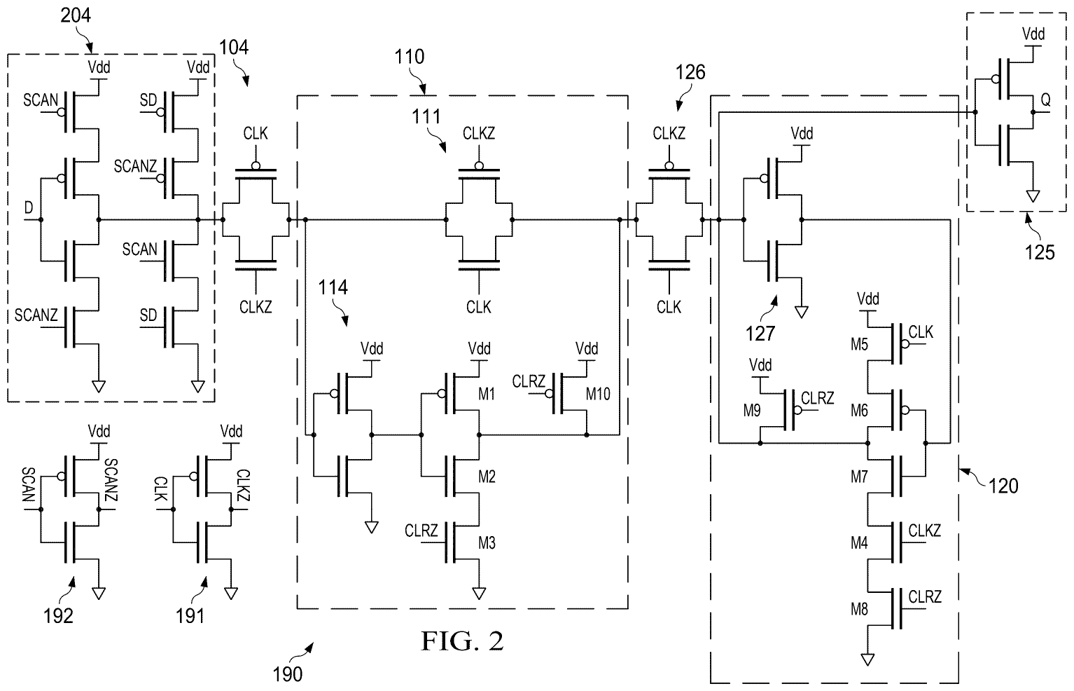

FIG. 2 is an example transistor-level illustration of flip-flop 190, according to some embodiments. The asynchronous clear functionality of latch 110 is provided by transistors M1-M3 and M10. Transistors M1 and M2 have their control terminals coupled to the output of inverter 114. Transistors M1 and M2 have their current path terminals (e.g., source/drain) coupled. Transistor M1 is coupled to a supply terminal (VDD). Transistor M2 has a current path terminal coupled to a current path terminal of transistor M3. M3 receives the asynchronous clear signal clrz at its control terminal (e.g., gate) and has a current path terminal coupled to a complementary supply terminal (e.g., ground).

Transistor M10 has a current path terminal coupled to the supply terminal and another current path terminal coupled to an output of the master latch 110. The control terminal of transistor M10 is configured to receive the clrz signal. As shown, when clrz is a digital 0, that causes transistor M10 to turn ON and causes transistor M3 to turn OFF, thereby causing master latch 110 to store a digital 1. Inverter 125 causes the output (q) to be a digital 0. Inverter 192 receives scan and outputs scanz.

The asynchronous clear functionality of the slave latch 120 is provided by transistors M4-M9. Transistors M5-M7, M4, and M8 are coupled in series, where transistor M5 is coupled to the supply terminal, transistor M8 is coupled to the complementary supply terminal, and each of the transistors M5-M7, M4, and M8 are coupled by their current path terminals, thereby creating a path from the supply terminal to the complementary supply terminal. Transistor M9 is coupled to the supply terminal by a first current path terminal and is coupled to the input of inverter 127 by another current path terminal. The control terminal of transistor M9 is configured to receive the clrz signal.

Transistors M6 and M7 are configured to receive the output of inverter 127 at their respective control terminals. Transistor M5 is configured to receive an inverted clock signal (clk) at its control terminal, and transistor M4 is configured to receive the clock signal clkz at its control terminal. Transistor M8 is configured to receive the clear signal at its control terminal.

Therefore, when the clear signal clrz is a 0, that turns transistor M9 ON and turns transistor M8 OFF, thereby causing a digital 1 to appear at the input of inverters 127 and 125 and driving the output q to zero.

Note in FIGS. 1 and 2 that the master latch 110 and the slave latch 120 are independently able to be cleared using the active-low clrz signal. Furthermore, transistors M3 and M8 are controlled by the clear signal and are both coupled to the complementary supply terminal. The architecture shown in FIG. 2 has 34 transistors total, out of which four are controlled by the clear signal.

FIG. 3 is an illustration of flip-flop 390, according to some embodiments. Flip-flop 390 achieves the same or nearly the same functionality as flip-flop 190 but with a smaller quantity of transistors.

Master latch 110 of FIG. 3 includes transistors M1-M3, arranged as in FIG. 2. However, master latch 110 omits transistor M10 because a single clear-controlled P type metal oxide semiconductor (PMOS) transistor (e.g., M9) provides asynchronous clear functionality for the flip-flop 390 as a whole. The omission of transistor M10 provides a savings of one transistor versus the architecture of FIG. 2.

Furthermore, slave latch 120 omits transistor M8. Slave latch 120 achieves pull down (e.g., low-side) functionality by shorting a current path terminal of transistor M4 to a current path terminal of transistor M3. Transistors M4, M8, and M3 in this example are N-type metal oxide semiconductor (NMOS) transistors. Thus, transistor M4 is pulled low when the clear signal clrz is a digital 1 that turns ON transistor M3.

In this example, when the clear signal clrz is a digital 1, the transistor M3 is ON, thereby discharging the stack having transistors M1 and M2 as well as the stack having transistors M4-M7. Both master latch 110 and slave latch 120 then operate normally, storing data based on either d or sd.

When the clear signal is a digital zero, then the flip-flop 390 is reset. For instance, when clk is a digital 0 (or when clkz is a digital 1) and when clrz is 0, then transistor M9 causes the inputs of inverters 127 and 125 to go high, thereby causing the output q to go low. The architecture of flip-flop 390 ensures that the internal nodes are properly driven to either a logic 0 or a logic 1, with only the output node of master latch 110 perhaps remaining un-driven in some states. However, when clk is a digital 0, then transmission gate 126 is OFF, which means that the data from the master latch 110 does not override the state stored in the slave latch 120. In one example, the input to transmission gate 111 and the input to inverter 114 is 0, the output of inverter 114 is 1, and NMOS transistor M2 is ON. If NMOS transistor M7 is also ON, then a logic 1 at the input of inverter 127 may come as a weak logic 1 until transmission gate 126 turns ON. But this weak logic 1 should not cause any internal nodes to change state because the transmission gates 111 and 126 are turned OFF. Similarly, if the output of transmission gate 104 and the input of inverter 114 is at a digital 1, then that causes the output of inverter 114 to go to a digital 0, which causes the output of the slave latch 110 (e.g., the input of transmission gate 126) to go to a digital 1 by PMOS transistor M1 being ON.

Turning to a scenario in which clk is a digital 1 (clkz is a digital 0) and clrz is 0, then the input to inverters 125 and 127 is a digital 1, causing the output q to go to digital 0. In this scenario, both transmission gate 111 and transmission gate 126 are ON, so the digital 1 at the input of inverter 127 will drive the input and the output of master latch 110 to a digital 1. However, the input does not write to the master latch 110 because transmission gate 104 is OFF.

The implementation of FIG. 3 shares functionality between latches of a same flip-flop device. In doing so, the implementation of FIG. 3 achieves a savings of two transistors versus the implementation of FIG. 2 by omitting PMOS transistor M10 and NMOS transistor M8.

FIG. 4 is an illustration of flip-flop 490, according to some embodiments. Flip-flop 490 operates in a similar manner as flip-flop 190. Flip-flop 490, however, provides preset functionality, as explained in more detail below. Master latch 430 receives input via transmission gate 104 from inverting multiplexer 204. Slave latch 440 receives a signal at its input from the output of master latch 430 via transmission gate 126.

Master latch 430 includes NAND gate 433 having an input coupled to the output of transmission gate 104 and another input configured to receive a preset (prez) signal. The output of NAND gate 433 is coupled to the input of inverter 434. The output of inverter 434 is coupled to the output of master latch 430 and to the input of transmission gate 126.

Slave latch 440 includes at its input NAND gate 448. One input of NAND gate 448 is coupled to the output of master latch 430. The other input of NAND gate 448 is configured to receive the preset signal. The output of NAND gate 448 is coupled to an input of tri-state inverter 449. Tri-state inverter 449 is controlled by the clkz signal. The output of tri-state inverter 449 is coupled to the input of slave latch 440 and to the input of inverter 125. The output signal q is at the output of inverter 125 to prevent loading directly on slave latch 440. In another implementation (not shown), output of flip-flop 490 may be taken from the output of NAND gate 448.

Flip-flop 490 is configured so that the preset signal prez is active-low, so that when the preset signal is a digital 0, it forces the output q to a digital 1.

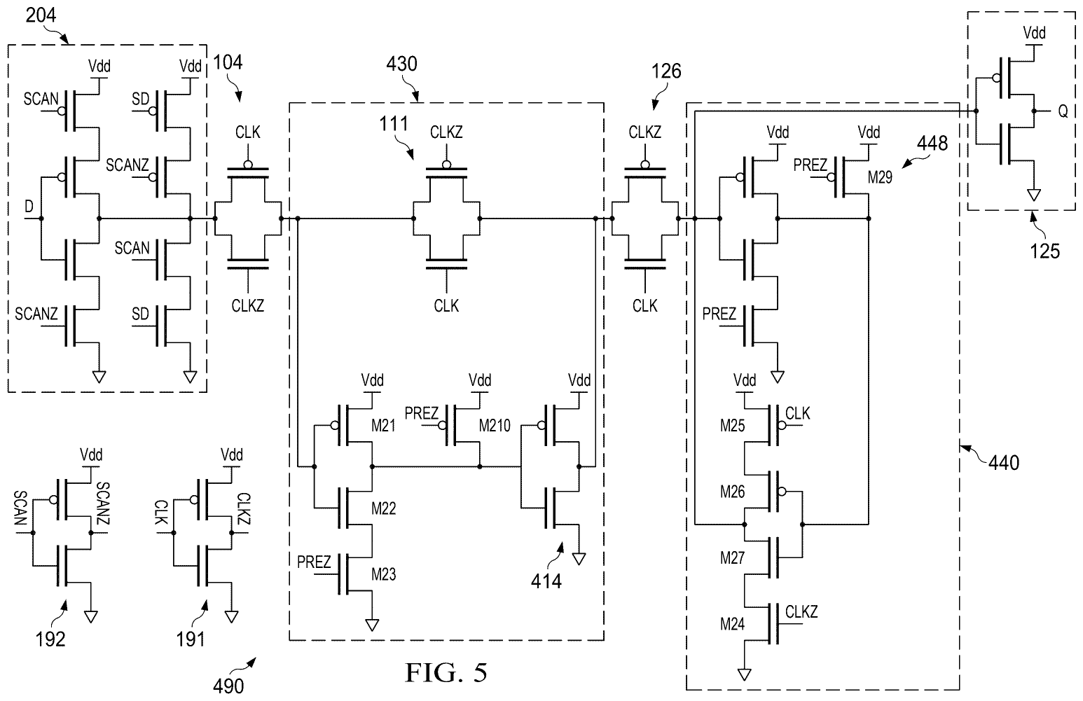

FIG. 5 is an example transistor-level illustration of flip-flop 490, according to some embodiments. Master latch 430 includes transistors M21-M23. Transistors M21 and M22 have their control terminals coupled to the input of master latch 430 and the output of transmission gate 104. The transistors M21 and M22 are coupled at their current path terminals, as are transistors M22 and M23. Transistor M21 is a PMOS transistor, and transistors M22 and M23 are NMOS transistors in this example. Transistor M210 is a PMOS transistor, and both transistors M23 and M210 are controlled by the preset signal. When the preset signal prez is low, it turns transistor M210 ON and turns transistor M23 OFF. Transistor M210 is coupled to a supply terminal (e.g., VDD) so that when transistor M210 is ON, it causes a digital 1 at the input of inverter 414, which results in the output of master latch 430 being at a digital 0.

Slave latch 440 includes transistors M25, M26, M27, and M24 arranged in series from a supply terminal to a complementary supply terminal (e.g., ground). The transistors M25, M26, M27, and M24 are coupled current path terminal-to-current path terminal and form clock-controlled tri-state inverter 449. Transistor M25 is a PMOS transistor controlled by the complementary clock signal clk, and transistor M24 is an NMOS transistor controlled by the clock signal clkz. Transistors M26 and M27 are both gate coupled to an output of NAND gate 448. Transistor M29 is a PMOS transistor that is controlled by the preset signal and is coupled to the supply terminal and the control terminals of PMOS transistor M26 and NMOS transistor M27.

When the preset signal prez is a digital 0, that turns transistor M29 ON, and causes a digital 1 to be applied to the control terminals of transistors M26 and M27, which propagates a digital 0 to the input of inverter 125, thereby causing the output q to go to digital 1.

The architecture illustrated in FIG. 5 utilizes 34 transistors.

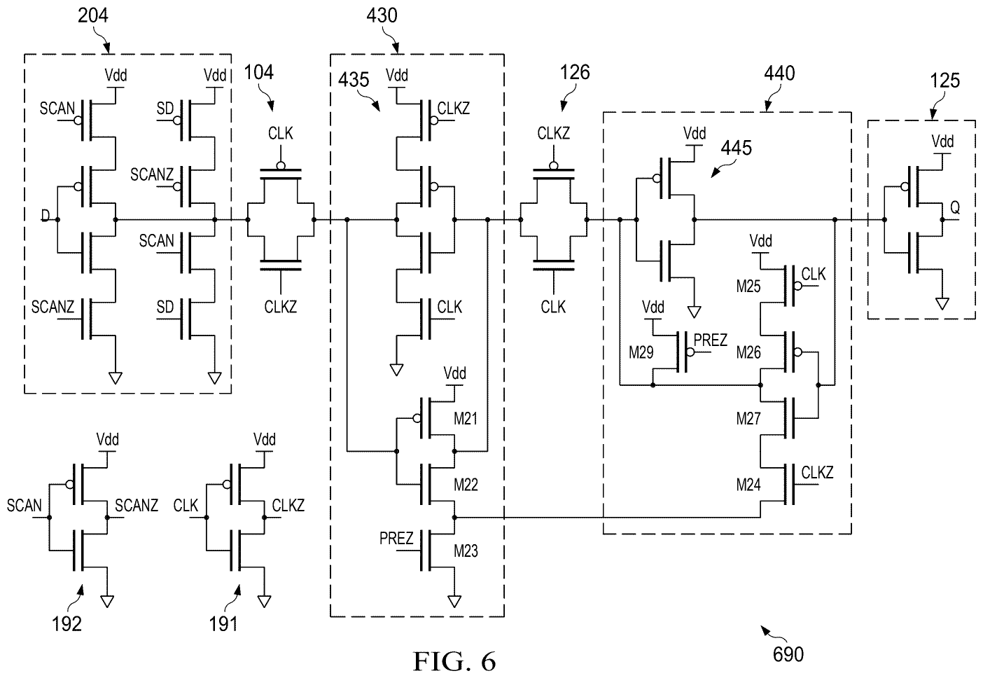

FIG. 6 is an illustration of an example scan flip-flop 690, according to some embodiments. Flip-flop 690 includes the same or similar functionality as described above with respect to flip-flop 490, though the architecture of flip-flop 690 saves two transistors compared to flip-flop 590.

In flip-flop 690, master latch 430 is reconfigured to have at its input a tri-state inverter 435. Tri-state inverter 435 has its input coupled to the output of master latch 430 and the output of tri-state inverter 435 is coupled to the input of master latch 430 and to the control terminals of transistors M21 and M22. Master latch 430 omits preset-controlled transistor M210 for a savings of one PMOS transistor.

Slave latch 440 includes inverter 445 having its input at the input of slave latch 440 and the output of transmission gate 126. The output of inverter 445 is coupled to the input of inverter 125, and the output of inverter 125 produces the output q. Furthermore, the output of inverter 445 is coupled to the control terminals of transistors M26 and M27. Transistor M29 is moved so that one of its current path terminals is coupled to the current path terminals of transistors M26 and M27 and to the input of inverter 445. Of note is that the input of inverter 125 has been moved from the input of slave latch 440 and is now disposed at the output of inverter 445. Furthermore, a current path terminal of transistor M24 is shorted to a current path terminal of transistor M23.

NAND gate 448 of FIG. 5 has been replaced by inverter 445 and transistor M29 has been moved to the feedback portion of slave latch 440, thereby saving one NMOS transistor. Thus, the architecture of FIG. 6 has a savings of two transistors total. Nevertheless, the functionality of flip-flop 690 is the same as that of flip-flop 490. Specifically, either the functional data or the scan data is passed through master latch 430 and slave latch 440 with each clock cycle as long as the preset signal prez is a digital 1. However, once the prez signal goes to a digital 0, the output of flip-flop 690 is forced to a digital 1, regardless of the values of the clock signals, the scan signal, d or sd.

Similar to the asynchronous clear examples above, the preset example of FIG. 6 shorts a current path terminal of a transistor in a slave latch to a current path terminal of another transistor in a master latch and further omits a PMOS transistor directly controlled by the asynchronous signal (e.g., clrz or prez).

FIG. 7 illustrates multi-bit flip-flop 790, according to some embodiments. Multi-bit flip-flop 790 illustrates two flip-flop stages 750 and 760. The flip-flop stage 750 includes master latch 110 and slave latch 120 and is arranged according to the architecture described above with respect to FIGS. 1-2.

The flip-flop stage 760 is structurally the same as the flip-flop stage 750. The output of the flip-flop stage 750 is designated as Q0, and it is applied to the scan data input of the flip-flop stage 760. Though flip-flop 790 is shown as including two flip-flop stages, it is understood that the flip-flop 790 may be scaled to include any appropriate number of stages by routing the output of one stage to the scan data input of the subsequent stage and repeating that pattern through the total number of stages. In the multi-bit example of FIG. 7, each of the flip-flop stages 750, 760 may be understood as a separate single-bit flip-flop circuit. When the scan signal(s) is set to digital 1, that causes the scan data (sd) to be passed from the first stage, through any intermediate stages, and to the output of the last stage (e.g., Q1). Otherwise, when the scan signal is a digital 0, each flip-flop stage passes a separate respective data bit through its latches. For instance, flip-flop stage 750 may pass the data bit D0 to its output Q0, and flip-flop stage 760 may pass the data bit D1 through its latches 730, 740 to its output Q1.

Furthermore, each flip-flop stage 750, 760 includes asynchronous clear functionality provided by PMOS transistors M10, M9, M310, and M39. The PMOS transistors M10, M9, M310, and M39 receive the clear signal clrz at their control terminals. When either transistor M10 or transistor M9 receives clrz as digital 0, that forces the output of flip-flop stage 750 to digital 0. Similarly, when either transistor M310 or transistor M39 receives clrz as digital 0, that forces the output of flip-flop stage 760 to digital zero.

Looking at master latch 730, transistors M31-M33 are arranged just as transistors M1-M3 of master latch 110. Looking at slave latch 740, transistors M35-M38 are arranged just as transistors M5-M8 of slave latch 120. For instance, transistors M31 and M32 are arranged as an inverter, with transistor M32 having a current path terminal coupled to a current path terminal of NMOS transistor M33. M33 is controlled by the clrz signal and acts as a pulldown (low-side) transistor when ON.

In slave latch 120, transistors M4-M8 are arranged as in FIG. 2, except that transistors M5 and M6 are transposed. Nevertheless, the transposition of transistors M5 and M6 does not change the functionality of flip-flop stage 750. Transistors M4-M7 are arranged as a clock-controlled tri-state inverter, receiving as an input the output from inverter 127 and with NMOS transistor M8 acting as a clrz-controlled pulldown transistor when ON.

In slave latch 740, transistors M34-M38 are arranged as described above with respect to transistors M4-M8 of slave latch 120.

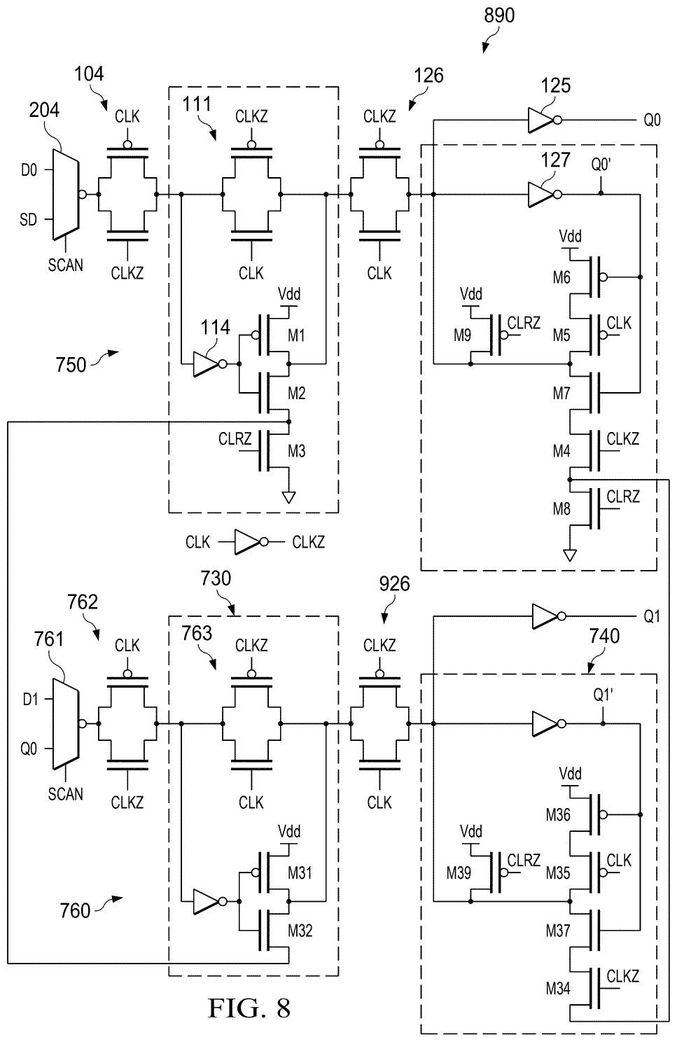

FIG. 8 is an illustration of example multi-bit flip-flop 890, according to some embodiments. Flip-flop 890 has a same functionality as that described above with respect to flip-flop 790; however, flip-flop 890 has an architecture that saves a quantity of transistors, as described further below.

For example, multibit flip-flop 890 omits clrz-controlled PMOS transistors M10 and M310 from master latches 110 and 730. Thus, master latches 110 and 730 may rely on the asynchronous clear functionality of slave latches 120 and 740, respectively. In a two-bit flip-flop, such change saves two PMOS transistors.

Transistors M2 and M3 are coupled by their current path terminals. Furthermore, a current path terminal of NMOS transistor M32 is coupled to the current path terminals of M2 and M3. Therefore, in this example, master latch 730 may omit NMOS transistor M33, instead, relying upon NMOS transistor M3 of master latch 110 as a pulldown transistor. Omitting NMOS transistor M33 produces a savings of one NMOS transistor.

Transistors M4 and M8 are coupled by their current path terminals. A current path terminal of transistor M34 is shorted to the current path terminals of transistors M4 and M8. Furthermore, slave latch 740 may then omit NMOS transistor M38, instead, relying on transistor M8 as a pulldown transistor. Omitting transistor M38 may produce a savings of one NMOS transistor.

Of note in this example is that master latch 110 and master latch 730 share NMOS pulldown functionality, so that the sharing is between flip-flop stages 750, 760. Similarly, slave latch 120 and slave latch 740 share NMOS pulldown functionality, so that the sharing is between flip-flop stages 750, 760. This is in contrast to the NMOS sharing of FIGS. 3 and 6, where NMOS sharing was between latches in a same flip-flop.

In the present example, omitting clrz-controlled PMOS transistors M10 and M310 is possible because as clk toggles, the transistors M9 and M39 of slave latches 120, 740 may also drive the internal states of the respective master latches 110, 730.

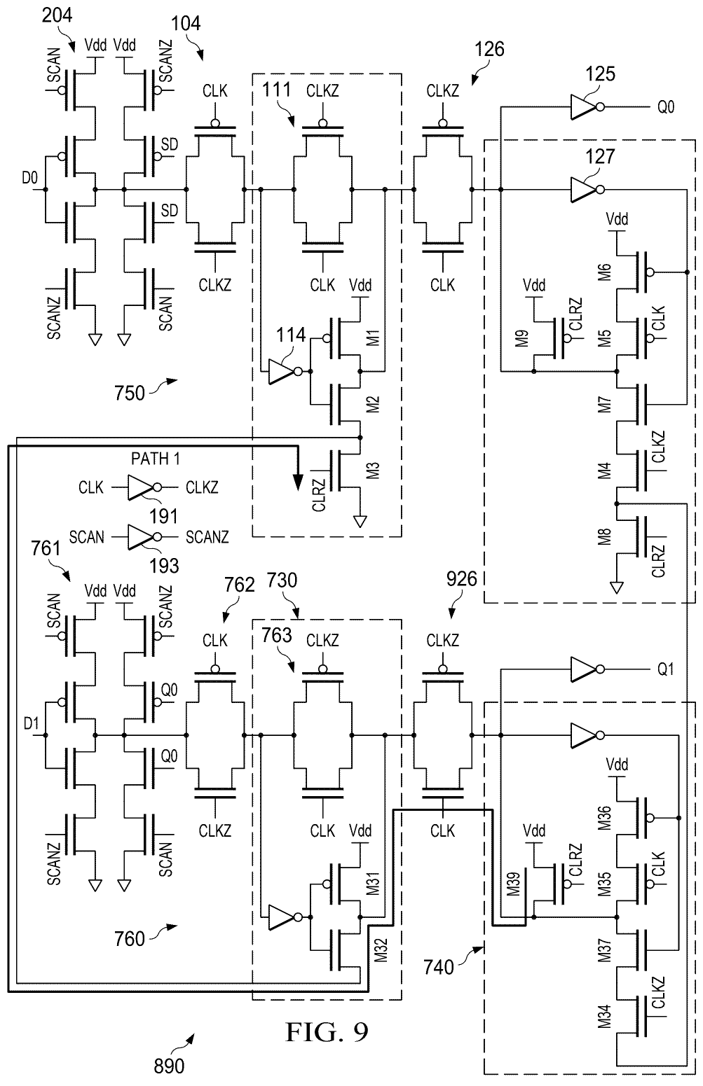

FIGS. 9-12 illustrate operation of multi-bit flip-flop 890, according to some embodiments. Specifically, each of FIGS. 9-12 illustrate a different possible current path from a supply terminal (e.g., VDD) to a complementary supply terminal (e.g., ground), where operation of multi-bit flip-flop 790 is expected to block current from traveling through those paths. For example, each of the operating modes of flip-flop 790 is expected to isolate the supply terminal from the complementary supply terminal, thereby preventing short circuit current and malfunctions.

Looking at FIG. 9 and Path 1 first, Path 1 is illustrated as starting at PMOS transistor M39, traversing from slave latch 740 through master latch 730 and NMOS transistor M32, through the shorted current path terminal of M32 to the current path terminal of NMOS transistor M3 to ground. In this example, PMOS transistor M39 and NMOS transistor M3 are both controlled by the clrz signal and are expected to be ON when the other is OFF and vice versa. Therefore, Path 1 does not experience a short circuit.

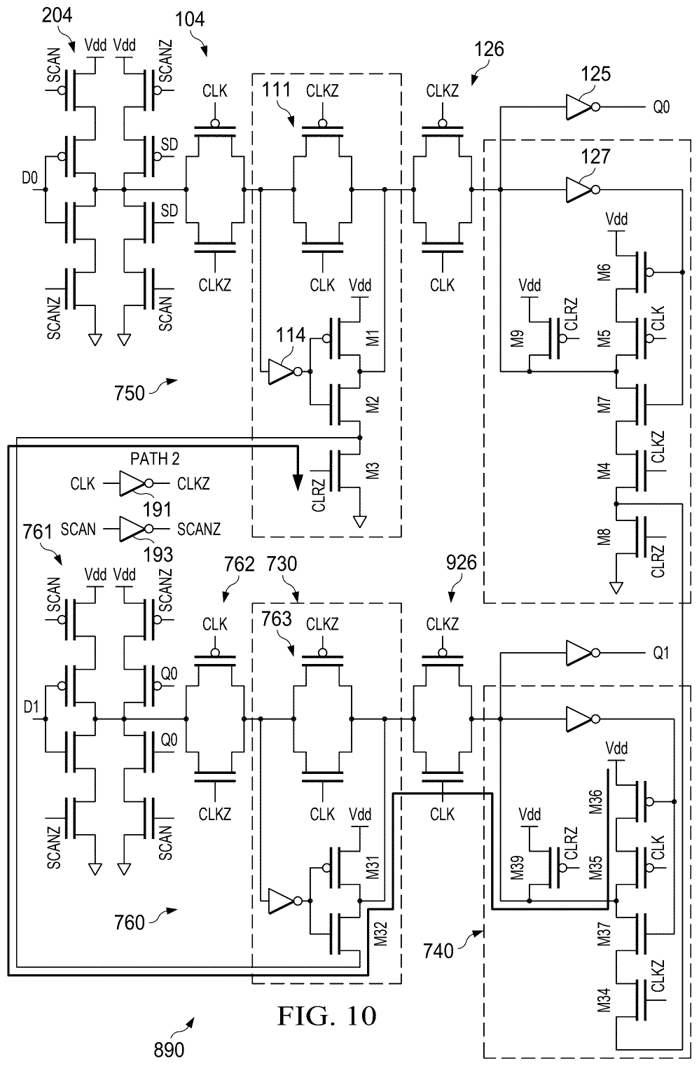

In FIG. 10, Path 2 traverses from PMOS transistor M36, through PMOS transistor M35, from slave latch 740 through master latch 730 and NMOS transistor M32, through the shorted current path terminal of M32 to the current path terminal of NMOS transistor M3 to ground. In this example, the PMOS transistor M35 and the clock-controlled transmission gate 926 have complementary operation so that one is ON when the other is OFF and vice versa. Therefore, Path 2 does not experience a short circuit.

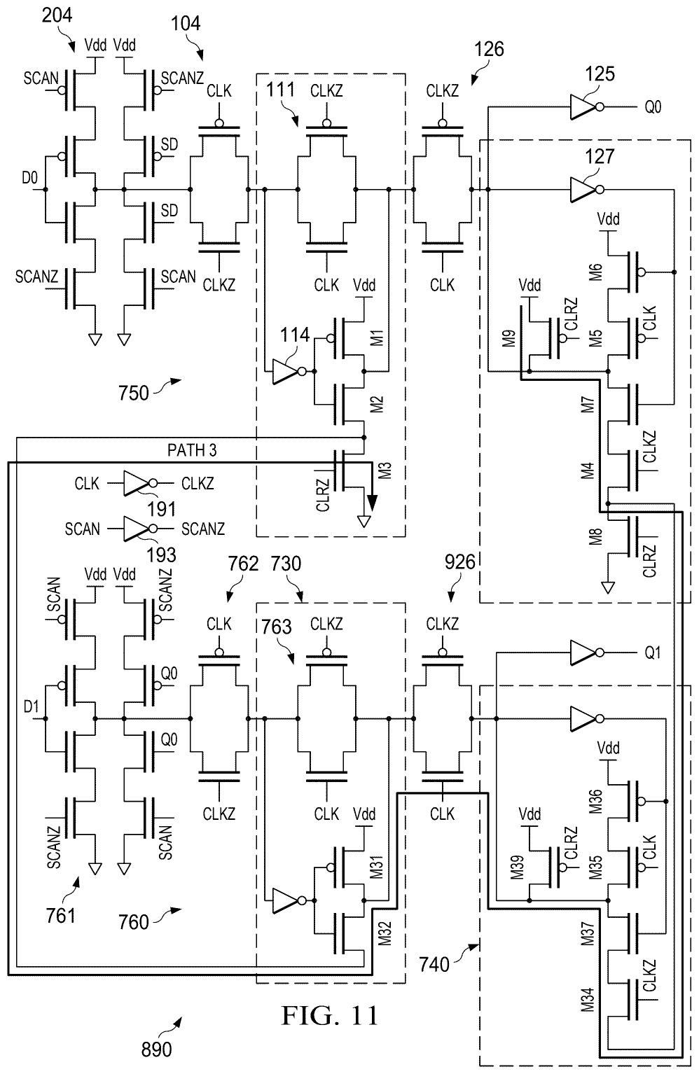

In FIG. 11, Path 3 begins at PMOS transistor M9, traverses through transistors M7 and M4, through the shorted current path terminal of M34 to the current path terminal of transistor M37, through transmission gate 926 to transistor M32, through the shorted current path terminal of transistor M32 to the current path terminal of M3 and through transistor M3. In Path 3, PMOS transistor M9 and NMOS transistor M3 are clrz-controlled and are complementary, thereby preventing a short circuit on Path 3.

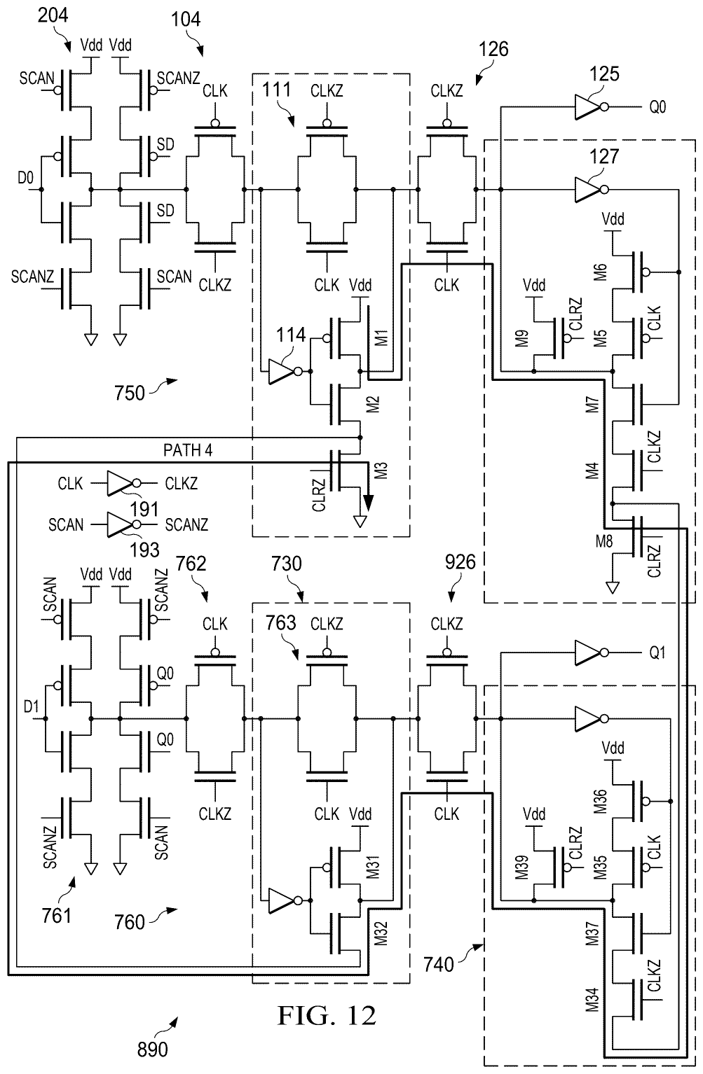

In FIG. 12, Path 4 begins at PMOS transistor M1, traverses through transmission gate 126, through NMOS transistors M7 and M4, through the shorted current path terminal of NMOS transistor M34, through transistor M37 and transmission gate 926, through NMOS transistor M32 and the shorted current path terminal of transistor M32 to the transistor M3. In Path 4, NMOS transistor M4 is complementary to transmission gates 126 and 926, thereby preventing a short circuit on Path 4.

Thus, as explained above, the various use cases of multi-bit flip-flop 890 may result in no short-circuit. Furthermore, as noted above, the architecture of multi-bit flip-flop 890 may reduce a quantity of transistors. Specifically, the savings may be one transistor for a first bit (a first flip-flop stage) and three transistors for each additional bit (additional flip-flop stages). So if an architecture of multi-bit flip-flop 890 has n stages, where n is an integer greater than 1, the transistor savings may be 1+3(n−1).

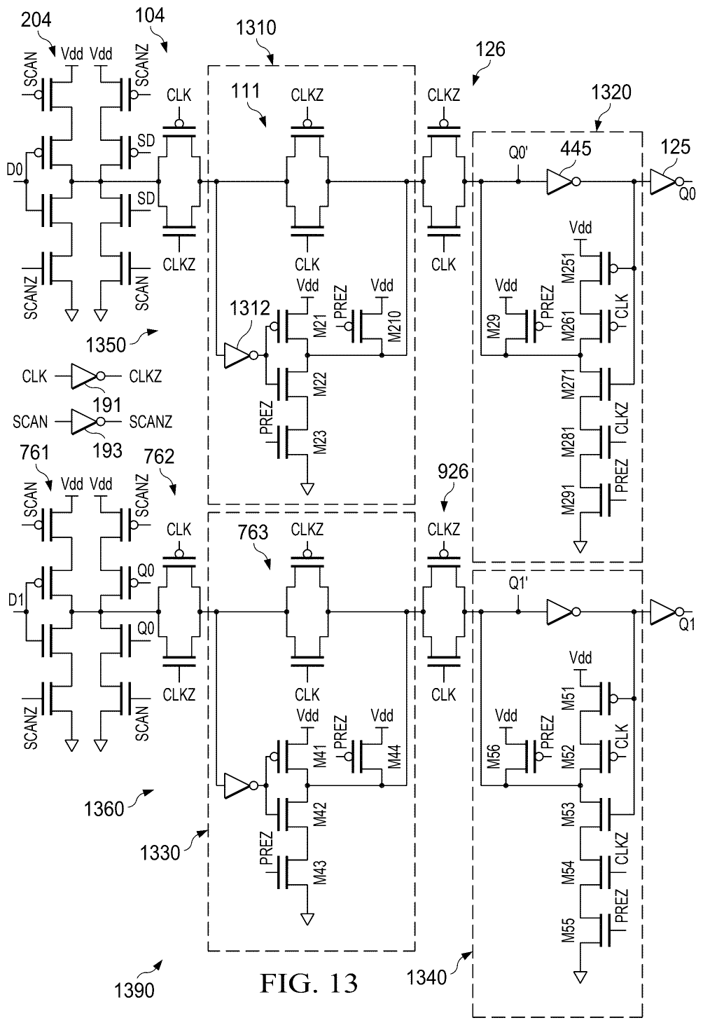

FIG. 13 is an illustration of an example multi-but flip-flop 1390, according to some embodiments. Just like flip-flop 790, flip-flop 1390 routes the output Q0 of its first flip-flop stage 1350 to a scan data input of flip-flop stage 1360. However, unlike flip-flop 790, flip-flop 1390 provides an asynchronous preset functionality rather than asynchronous clear functionality. When the preset signal prez is a digital 0, that forces the output of flip-flop stage 1350 and flip-flop stage 1360 to output a value of digital 1. This is true regardless of the value of functional data (d), scan data (sd), or the clock signal clkz. This concept was described above with respect to a single-bit flip-flop at the description of FIGS. 4-6, and FIG. 13 illustrates how that concept may be applied in a multi-bit context.

Flip-flop stage 1350 includes master latch 1310 and slave latch 1320. Master latch 1310 includes transistors M21, M22, and M23 arranged in series between a supply terminal (e.g., VDD) and a complementary supply terminal (e.g., ground). PMOS transistor M21 and NMOS transistor M22 form an inverter having control terminals configured to receive the output of inverter 1312. A current path terminal of transistor M22 is coupled to a current path terminal of NMOS transistor M23, which receives the preset signal at its control terminal. PMOS transistor M210 is coupled between a supply terminal and the output of master latch 1310. NMOS transistor M23 acts as a pulldown transistor.

Transistors M41-M44 are arranged in master latch 1330 in the same manner as transistors M21-M210 are arranged in master latch 1310.

Transistors M251, M261, M271, and M281 are arranged as a clock-controlled tri-state inverter in slave latch 1320. NMOS transistor M291 is configured as a pulldown transistor for the tri-state inverter, and transistor M291 is configured to receive the preset signal at its control terminal. PMOS transistor M251 and NMOS transistor M271 are configured to receive the output of inverter 445 at their control terminals. PMOS transistor M261 is configured to receive the complementary clock signal clk at its control terminal, and NMOS transistor M281 is configured to receive the clock signal clkz at its control terminal. Inverter 125 is disposed between the output of inverter 445 and the input of the tri-state inverter formed by transistors M251, M261, M271, and M281. PMOS transistor M29 is disposed so that one of its current path terminals is coupled to the output of the tri-state inverter of transistors M251, M261, M271, and M281 and to the input of inverter 445. The other current path terminal of transistor M29 is coupled to a supply terminal. Inverter 193 receives scan and outputs scanz.

Transistors M51-M56 are arranged in slave latch 1340 in the same manner as transistors M251, M261, M271, M281, and M29 are arranged in slave latch 1320.

The multi-bit flip-flop 1390 includes two flip-flop stages and, thus, four preset-controlled transistors (M23, M29, M43, M56). Additional stages (not shown) would each add two more preset control transistors.

In operation, each flip-flop stage 1350, 1360 passes either functional data or scan data from input to output with each clock cycle. However, if either of transistors M210 or M29 receives a preset signal as a digital 0, that will cause the output of flip-flop stage 1350 to be a digital 1. Similarly, if either of transistors M44 or M56 receives a preset signal is a digital 0, that will cause the output of flip-flop stage 1360 to be a digital 1.

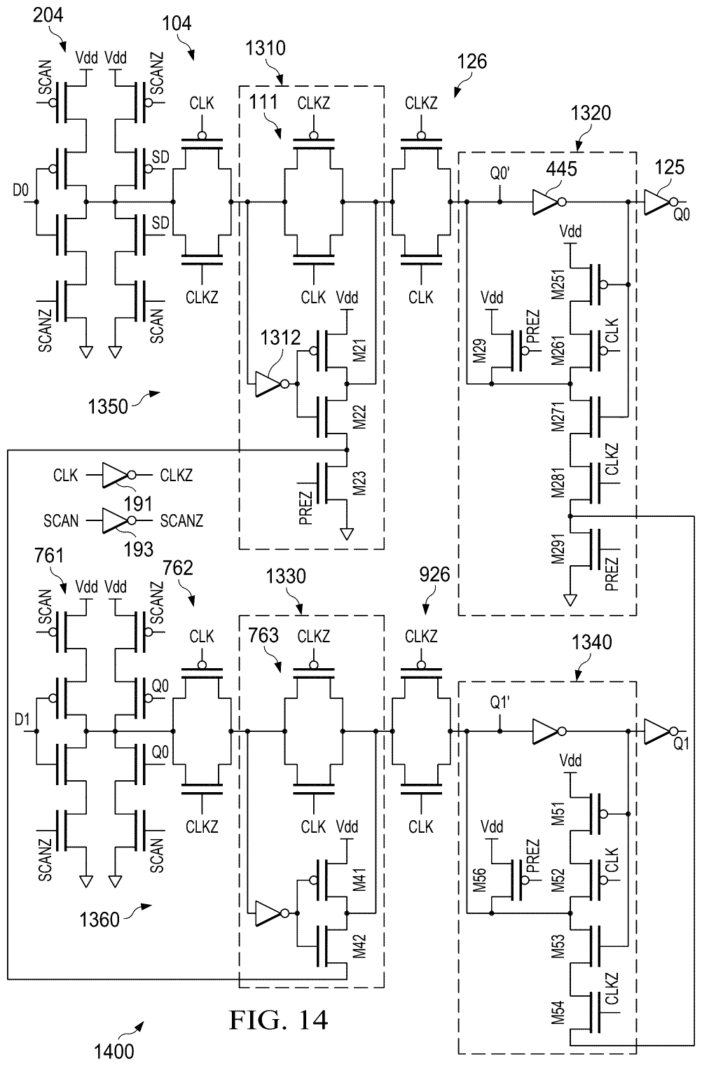

FIG. 14 is an illustration of example multi-bit flip-flop 1400, according to some embodiments. Flip-flop 1400 has the same or similar logical functionality as described above with respect to flip-flop 1390, though the architecture of flip-flop 1400 reduces a quantity of transistors. Furthermore, although FIG. 14 is shown as having only two stages, it is understood that number of stages may be scaled by linking the output of one stage to the scan data input of the next stage and on and on. The number of stages may be n, with n being an integer greater than 1.

Flip-flop 1400 omits PMOS transistors M210 and M44 from master latches 1310, 1330. Thus, flip-flop 1400 relies on PMOS transistors M29 and M26 for preset functionality. Such feature reduces the number of PMOS transistors by one for each flip-flop stage.

Flip-flop 1400 also omits NMOS transistor M43 from master latch 1330 and NMOS transistor M55 from slave latch 1340. Master latch 1330 shorts a current path terminal of NMOS transistor M42 to a current path terminal of NMOS transistor M23. Slave latch 1340 shorts a current path terminal of NMOS transistor M54 to a current path terminal of NMOS transistor M291. NMOS transistors M23 and M291 are both controlled by the preset signal, as are the omitted transistors M43 and M55. The omission of transistors M43 and M55 reduces the number of NMOS transistors by two for each flip-flop stage.

Of note in this example is that the NMOS sharing from master latch 1310 to master latch 1330 is from one flip-flop stage 1350 to another flip-flop stage 1360. Similarly, the NMOS sharing from slave latch 1322 slave latch 1340 is from one flip-flop stage 1350 to another flip-flop stage 1360.

The implementations of FIGS. 8 and 14 may be further modified to reduce additional transistors. For instance, looking at FIG. 8, transistor M3 and transistor M8 are both NMOS devices controlled by the clrz signal. There is a first node where transistor M2 couples to transistor M3, and there is a second node at which transistor M4 couples to transistor M8. A further embodiment may short the first node to the second node and then omit transistor M8. Such embodiment applies the principle of FIG. 3 to the architecture of FIG. 8.

Similarly, looking at FIG. 14, there is a first node where transistor M22 couples to transistor M23, and there is a second node where transistor M281 couples to transistor M291. A further embodiment may short the first node to the second node and then omit transistor M291 because transistors M23 and M291 are both prez-controlled NMOS devices. Once again, this embodiment applies the principle of FIG. 3, but to the architecture of FIG. 14.

Various embodiments described herein may be used to reduce a quantity of transistors in a logic circuit, such as a flip-flop or a flip-flop stage. For instance, some of the embodiments may save two transistors or even more, depending on the quantity of flip-flop stages or whether the logic circuit has an asynchronous clear functionality or an asynchronous preset functionality. An advantage of using a reduced quantity of transistors may include saving area in a semiconductor circuit, especially when such logic circuits may be implemented in relatively large numbers within the semiconductor circuit. A reduction in transistors may allow for a reduction in leakage current and in operating current as well.

Various embodiments may implement logic circuits, such as flip-flops, in various applications. One such application may include a frequency divider circuit, which may include multiple flip-flops arranged serially. Furthermore, flip-flops may be used as digital storage elements in digital processing circuits. In fact, logic circuits may be implemented in many different applications. Furthermore, such circuits may be implemented on semiconductor dies, and the semiconductor dies may further be implemented in semiconductor packages.

Example embodiments of the present disclosure are summarized here. Other embodiments can also be understood from the entirety of the specification and the claims filed herein.

Example 1. A circuit including: a first latch having a first logic gate that includes a first transistor having first and second current path terminals; and a second latch having a second logic gate that includes a second transistor having first and second current path terminals, where the first current path terminal of the first transistor is shorted to the second current path terminal of the second transistor, and where the second current path terminal of the first transistor is coupled to a ground terminal.

Example 2. The circuit of example 1, where the first and second transistors are pulldown transistors.

Example 3. The circuit of one of examples 1 or 2, where the second logic gate includes: a third transistor having a first current path terminal coupled to a supply terminal, and a second current path terminal; a fourth transistor having a first current path terminal coupled to the second current path terminal of the third transistor, and a second current path terminal; and a fifth transistor having a first current path terminal coupled to the second current path terminal of the fourth transistor and a second current path terminal coupled to the first current path terminal of the second transistor.

Example 4. The circuit of one of examples 1 to 3, where a control terminal of the fourth transistor is shorted with a control terminal of the fifth transistor.

Example 5. The circuit of one of examples 1 to 4, where the first logic gate includes: a sixth transistor having a first current path terminal coupled to the supply terminal and a second current path terminal; and a seventh transistor having a first current path terminal coupled to the second current path terminal of the sixth transistor, and a second current path terminal coupled to the first current path terminal of the first transistor.

Example 6. The circuit of one of examples 1 to 5, where the first latch includes an output, and where the second latch includes an input coupled to the output of the first latch.

Example 7. The circuit of one of examples 1 to 6, further including a transmission gate coupled between the output of the first latch and the input of the second latch.

Example 8. The circuit of one of examples 1 to 7, where the transmission gate is configured to be controlled by a clock signal, and where a control terminal of the second transistor is configured to be controlled by the clock signal.

Example 9. The circuit of one of examples 1 to 8, where the first transistor includes a control terminal configured to receive an asynchronous clear signal, where the first latch is configured to clear responsive to the asynchronous clear signal being asserted, and where the second transistor includes a control terminal configured to receive a clock signal.

Example 10. The circuit of one of examples 1 to 9, where the first latch further includes a transmission gate configured to be controlled by the clock signal.

Example 11. The circuit of one of examples 1 to 10, where the first transistor is an N-type metal oxide semiconductor (NMOS) device, further where the second transistor is an NMOS device.

Example 12. The circuit of one of examples 1 to 11, where the second latch further includes a third transistor coupled between a supply terminal and an input of the second latch, where the third transistor is a P-type metal oxide semiconductor (PMOS) device configured to receive the asynchronous clear signal.

Example 13. The circuit of one of examples 1 to 12, where: the second latch includes a third transistor having a current path coupled between a supply terminal and an input of the second latch, and a control terminal configured to receive an asynchronous clear signal, and the first latch does not include a transistor arranged between the supply terminal and an output of the first latch and configured to receive the asynchronous clear signal, where the first latch is configured to clear responsive to the asynchronous clear signal being asserted.

Example 14. The circuit of one of examples 1 to 13, where the second latch includes: a third transistor having a first current path terminal coupled to a supply terminal, and a second current path terminal; a fourth transistor having a first current path terminal coupled to the second current path terminal of the third transistor, and a second current path terminal; and a fifth transistor having a first current path terminal coupled to the second current path terminal of the fourth transistor and a second current path terminal coupled to the first current path terminal of the second transistor; an output coupled to the control terminals of the fourth and fifth transistors; an input coupled to the second current path terminal of the fourth transistor; an inverter having an input coupled to the input of the second latch and an output coupled to the output of the second latch; and a sixth transistor having a first current path terminal coupled to the supply terminal, a second current path terminal coupled to the input of the second latch.

Example 15. The circuit of one of examples 1 to 14, where a control terminal of the sixth transistor is configured to receive a preset signal, where the second latch is configured to preset responsive to the preset signal being asserted.

Example 16. The circuit of one of examples 1 to 15, where the first logic gate includes: a seventh transistor having a first current path terminal coupled to the supply terminal and a second current path terminal; and an eighth transistor having a first current path terminal coupled to the second current path terminal of the seventh transistor, and a second current path terminal coupled to the first current path terminal of the first transistor.

Example 17. The circuit of one of examples 1 to 16, where the first transistor is an N-type metal oxide semiconductor (NMOS) device, further where the second transistor is an NMOS device.

Example 18. The circuit of one of examples 1 to 17, where the second transistor is configured to receive a clock signal, and where the first transistor is configured to receive the preset signal.

Example 19. The circuit of one of examples 1 to 18, where: the first latch does not include: a P-type metal oxide semiconductor (PMOS) transistor arranged between the supply terminal and an output of the first latch and configured to receive the preset signal, where the first latch is configured to preset responsive to the preset signal being asserted.

Example 20. The circuit of one of examples 1 to 19, where the first latch is included in a first flip-flop, and where the second latch is included in a second flip-flop, where the first flip-flop and the second flip-flop are arranged so that an output of the first flip-flop is coupled to an input of the second flip-flop.

Example 21. The circuit of one of examples 1 to 20, further including: a third latch, arranged in the first flip-flop; and a fourth latch, arranged in the second flip-flop, where a current path terminal of a third transistor of the third latch is shorted to a current path terminal of a fourth transistor of the fourth latch.

Example 22. The circuit of one of examples 1 to 21, where the third latch is coupled to the first latch and is configured to store a value received from the first latch.

Example 23. The circuit of one of examples 1 to 22, where the fourth latch is coupled to the second latch and is configured to store a value received from the second latch.

Example 24. The circuit of one of examples 1 to 23, where the first transistor is an N-type metal oxide semiconductor (NMOS) device having a gate configured to receive an asynchronous clear signal, and where the fourth transistor is an NMOS device having a gate configured to receive a clock signal.

Example 25. The circuit of one of examples 1 to 24, where: the third latch includes a fifth transistor, coupled between a supply terminal and an input of the third latch, where the fifth transistor is a P-type metal oxide semiconductor (PMOS) device configured to receive the asynchronous clear signal; and the fourth latch includes a sixth transistor, coupled between the supply terminal and an input of the fourth latch, where the sixth transistor is a PMOS device configured to receive the asynchronous clear signal.

Example 26. The circuit of one of examples 1 to 25, where the circuit includes a path from the sixth transistor to the second latch and to the first transistor through the second current path terminal of the second transistor, further where the first transistor and the sixth transistor are configured to isolate the supply terminal from the ground terminal through the path.

Example 27. The circuit of one of examples 1 to 26, where the fourth latch includes a first clock-controlled transistor, further where the circuit includes a path including the first clock-controlled transistor, a clock-controlled transmission gate, the second latch, and the second current path terminal of the second transistor, where the first clock-controlled transistor and the clock-controlled transmission gate are configured to isolate the supply terminal from the ground terminal through the path.

Example 28. The circuit of one of examples 1 to 27, where the circuit includes a path from the fifth transistor, through the third transistor and the fourth transistor, to the second latch and to the first transistor through the second current path terminal of the second transistor, where the fifth transistor and the first transistor are configured to isolate the supply terminal from the ground terminal through the path.

Example 29. The circuit of one of examples 1 to 28, where the circuit includes a first clock-controlled transmission gate between the first latch and the third latch and a second clock-controlled transmission gate between the fourth latch and the second latch, further where the circuit includes a path from the first latch through the first clock-controlled transmission gate, through the fourth transistor and the second clock-controlled transmission gate to the second latch and to the first transistor through the second current path terminal of the second transistor, where the fourth transistor, the first clock-controlled transmission gate, and the second clock-controlled transmission gate are configured to isolate the supply terminal from the ground terminal through the path.

Example 30. The circuit of one of examples 1 to 29, where the first transistor is an N-type metal oxide semiconductor (NMOS) device configured to receive a preset signal, and where the fourth transistor is a clock-controlled NMOS device.

Example 31. The circuit of one of examples 1 to 30, where: the third latch includes a fifth transistor, coupled between a supply terminal and an input of the third latch, where the fifth transistor is a P-type metal oxide semiconductor (PMOS) device configured to receive a preset signal; and the fourth latch includes a sixth transistor, coupled between the supply terminal and an input of the fourth latch, where the sixth transistor is a PMOS device configured to receive the preset signal.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A circuit comprising:
a first latch having a first logic gate that includes a first transistor having first and second current path terminals; and
a second latch having a second logic gate that includes a second transistor having first and second current path terminals, wherein the first current path terminal of the first transistor is shorted to the second current path terminal of the second transistor, and wherein the second current path terminal of the first transistor is coupled to a ground terminal.

2. The circuit of claim 1, wherein the first and second transistors are pulldown transistors.

3. The circuit of claim 1, wherein the second logic gate comprises:
a third transistor having a first current path terminal coupled to a supply terminal, and a second current path terminal;
a fourth transistor having a first current path terminal coupled to the second current path terminal of the third transistor, and a second current path terminal; and
a fifth transistor having a first current path terminal coupled to the second current path terminal of the fourth transistor and a second current path terminal coupled to the first current path terminal of the second transistor.

4. The circuit of claim 3, wherein a control terminal of the fourth transistor is shorted with a control terminal of the fifth transistor.

5. The circuit of claim 3, wherein the first logic gate comprises:
a sixth transistor having a first current path terminal coupled to the supply terminal and a second current path terminal; and
a seventh transistor having a first current path terminal coupled to the second current path terminal of the sixth transistor, and a second current path terminal coupled to the first current path terminal of the first transistor.

6. The circuit of claim 1, wherein the first latch comprises an output, and wherein the second latch comprises an input coupled to the output of the first latch.

7. The circuit of claim 6, further comprising a transmission gate coupled between the output of the first latch and the input of the second latch.

8. The circuit of claim 7, wherein the transmission gate is configured to be controlled by a clock signal, and wherein a control terminal of the second transistor is configured to be controlled by the clock signal.

9. The circuit of claim 1, wherein the first transistor comprises a control terminal configured to receive an asynchronous clear signal, wherein the first latch is configured to clear responsive to the asynchronous clear signal being asserted, and wherein the second transistor comprises a control terminal configured to receive a clock signal.

10. The circuit of claim 9, wherein the first latch further includes a transmission gate configured to be controlled by the clock signal.

11. The circuit of claim 9, wherein the first transistor is an N-type metal oxide semiconductor (NMOS) device, further wherein the second transistor is an NMOS device.

12. The circuit of claim 11, wherein the second latch further includes a third transistor coupled between a supply terminal and an input of the second latch, wherein the third transistor is a P-type metal oxide semiconductor (PMOS) device configured to receive the asynchronous clear signal.

13. The circuit of claim 1, wherein:
the second latch includes a third transistor having a current path coupled between a supply terminal and an input of the second latch, and a control terminal configured to receive an asynchronous clear signal, and
the first latch does not include a transistor arranged between the supply terminal and an output of the first latch and configured to receive the asynchronous clear signal, wherein the first latch is configured to clear responsive to the asynchronous clear signal being asserted.

14. The circuit of claim 1, wherein the second latch comprises:
a third transistor having a first current path terminal coupled to a supply terminal, and a second current path terminal;
a fourth transistor having a first current path terminal coupled to the second current path terminal of the third transistor, and a second current path terminal; and
a fifth transistor having a first current path terminal coupled to the second current path terminal of the fourth transistor and a second current path terminal coupled to the first current path terminal of the second transistor;
an output coupled to the control terminals of the fourth and fifth transistors;
an input coupled to the second current path terminal of the fourth transistor;
an inverter having an input coupled to the input of the second latch and an output coupled to the output of the second latch; and
a sixth transistor having a first current path terminal coupled to the supply terminal, a second current path terminal coupled to the input of the second latch.

15. The circuit of claim 14, wherein a control terminal of the sixth transistor is configured to receive a preset signal, wherein the second latch is configured to preset responsive to the preset signal being asserted.

16. The circuit of claim 14, wherein the first logic gate comprises:
a seventh transistor having a first current path terminal coupled to the supply terminal and a second current path terminal; and
an eighth transistor having a first current path terminal coupled to the second current path terminal of the seventh transistor, and a second current path terminal coupled to the first current path terminal of the first transistor.

17. The circuit of claim 16, wherein the first transistor is an N-type metal oxide semiconductor (NMOS) device, further wherein the second transistor is an NMOS device.

18. The circuit of claim 17, wherein the second transistor is configured to receive a clock signal, and wherein the first transistor is configured to receive the preset signal.

19. The circuit of claim 14, wherein:
the first latch does not include: a P-type metal oxide semiconductor (PMOS) transistor arranged between the supply terminal and an output of the first latch and configured to receive the preset signal, wherein the first latch is configured to preset responsive to the preset signal being asserted.

20. The circuit of claim 1, wherein the first latch is included in a first flip-flop, and wherein the second latch is included in a second flip-flop, wherein the first flip-flop and the second flip-flop are arranged so that an output of the first flip-flop is coupled to an input of the second flip-flop.

21. The circuit of claim 20, further comprising:
a third latch, arranged in the first flip-flop; and
a fourth latch, arranged in the second flip-flop, wherein a current path terminal of a third transistor of the third latch is shorted to a current path terminal of a fourth transistor of the fourth latch.

22. The circuit of claim 20, wherein the third latch is coupled to the first latch and is configured to store a value received from the first latch.

23. The circuit of claim 20, wherein the fourth latch is coupled to the second latch and is configured to store a value received from the second latch.

24. The circuit of claim 21, wherein the first transistor is an N-type metal oxide semiconductor (NMOS) device having a gate configured to receive an asynchronous clear signal, and wherein the fourth transistor is an NMOS device having a gate configured to receive a clock signal.

25. The circuit of claim 24, wherein:
the third latch includes a fifth transistor, coupled between a supply terminal and an input of the third latch, wherein the fifth transistor is a P-type metal oxide semiconductor (PMOS) device configured to receive the asynchronous clear signal; and
the fourth latch includes a sixth transistor, coupled between the supply terminal and an input of the fourth latch, wherein the sixth transistor is a PMOS device configured to receive the asynchronous clear signal.

26. The circuit of claim 25, wherein the circuit includes a path from the sixth transistor to the second latch and to the first transistor through the second current path terminal of the second transistor, further wherein the first transistor and the sixth transistor are configured to isolate the supply terminal from the ground terminal through the path.

27. The circuit of claim 25, wherein the fourth latch comprises a first clock-controlled transistor, further wherein the circuit comprises a path including the first clock-controlled transistor, a clock-controlled transmission gate, the second latch, and the second current path terminal of the second transistor, wherein the first clock-controlled transistor and the clock-controlled transmission gate are configured to isolate the supply terminal from the ground terminal through the path.

28. The circuit of claim 25, wherein the circuit comprises a path from the fifth transistor, through the third transistor and the fourth transistor, to the second latch and to the first transistor through the second current path terminal of the second transistor, wherein the fifth transistor and the first transistor are configured to isolate the supply terminal from the ground terminal through the path.

29. The circuit of claim 25, wherein the circuit comprises a first clock-controlled transmission gate between the first latch and the third latch and a second clock-controlled transmission gate between the fourth latch and the second latch, further wherein the circuit comprises a path from the first latch through the first clock-controlled transmission gate, through the fourth transistor and the second clock-controlled transmission gate to the second latch and to the first transistor through the second current path terminal of the second transistor, wherein the fourth transistor, the first clock-controlled transmission gate, and the second clock-controlled transmission gate are configured to isolate the supply terminal from the ground terminal through the path.

30. The circuit of claim 21, wherein the first transistor is an N-type metal oxide semiconductor (NMOS) device configured to receive a preset signal, and wherein the fourth transistor is a clock-controlled NMOS device.

31. The circuit of claim 30, wherein:
the third latch includes a fifth transistor, coupled between a supply terminal and an input of the third latch, wherein the fifth transistor is a P-type metal oxide semiconductor (PMOS) device configured to receive a preset signal; and
the fourth latch includes a sixth transistor, coupled between the supply terminal and an input of the fourth latch, wherein the sixth transistor is a PMOS device configured to receive the preset signal.
